(19) United States
(12) Patent Application Publication
(10) Pub. No.: US 2023/0352909 A1
(43) Pub. Date: Nov. 2, 2023

(54) SEMICONDUCTOR LASER AND METHOD OF MANUFACTURING SAME

(71) Applicants: NICHIA CORPORATION, Anan-shi (JP); KYOTO UNIVERSITY, Kyoto-shi (JP)

(72) Inventors: Atsuo MICHIUE, Anan-shi (JP); Kunimichi OMAE, Anan-shi (JP); Shunsuke MINATO, Anan-shi (JP); Susumu NODA, Kyoto-shi (JP)

(73) Assignees: NICHIA CORPORATION, Anan-shi (JP); KYOTO UNIVERSITY, Kyoto-shi (JP)

(21) Appl. No.: 18/307,564

(22) Filed: Apr. 26, 2023

(30) Foreign Application Priority Data
Apr. 28, 2022 (JP) 2022-075205

(51) Int. Cl. H01S 5/11; H01S 5/343

(52) U.S. Cl. CPC H01S 5/11; H01S 5/34333

(57) ABSTRACT

A semiconductor laser includes: a first semiconductor layer part including a semiconductor layer of a first conductivity type; an active layer disposed on the first semiconductor layer part; a second semiconductor layer part disposed on the active layer and including a semiconductor layer of a second conductivity type; a third semiconductor layer p100415-0433art disposed on the second semiconductor layer part and including a semiconductor layer containing a first concentration of an impurity of the first conductivity type; and a fourth semiconductor layer part disposed on the third semiconductor layer part and including a semiconductor layer containing a second concentration of the impurity of the first conductivity type, the second concentration being lower than the first concentration. The third semiconductor layer part is directly bonded to the fourth semiconductor layer part. At least one of the third semiconductor layer part or the fourth semiconductor layer part includes a photonic crystal.

### CROSS-REFERENCE TO RELATED APPLICATIONS

The present application claims priority under 35 U. S. C. § 119 to Japanese Patent Application No. 2022-075205, filed Apr. 28, 2022, the contents of which are incorporated herein by reference in their entirety.

### BACKGROUND

The present disclosure relates to a semiconductor laser and a method of manufacturing the semiconductor laser.

In recent years, development of a semiconductor light emitting element that utilizes a photonic crystal has been actively pursued. Such a semiconductor light emitting element is utilized in a semiconductor laser or the like. For example, Japanese Patent Publication No. 2009-54864 discloses a gallium nitride-based semiconductor surface light emitting element.

However, semiconductor lasers or the like that utilize photonic crystals are still in early stages of development and have room for improvement.

### SUMMARY

One object of the present disclosure is to provide a semiconductor laser that includes a photonic crystal and a method of manufacturing the semiconductor laser.

A semiconductor laser according to an embodiment of the present disclosure includes a first semiconductor layer part including a semiconductor layer of a first conductivity type, an active layer disposed on the first semiconductor layer part, a second semiconductor layer part disposed on the active layer and including a semiconductor layer of a second conductivity type, a third semiconductor layer part disposed on the second semiconductor layer part and including a semiconductor layer containing a first concentration of an impurity of the first conductivity type, and a fourth semiconductor layer part disposed on the third semiconductor layer part and including a semiconductor layer containing a second concentration of an impurity of the first conductivity type, the first concentration being higher than the second concentration, the third semiconductor layer part being directly bonded to the fourth semiconductor layer part, and at least either the third semiconductor layer part or the fourth semiconductor layer part including a photonic crystal.

A method of manufacturing a semiconductor laser according to an embodiment of the present disclosure includes: a step of preparing a semiconductor part that includes a first semiconductor layer part including a semiconductor layer of a first conductivity type, an active layer disposed on the first semiconductor layer part, a second semiconductor layer part disposed on the active layer and including a semiconductor layer of a second conductivity type, and a third semiconductor layer part disposed on the second semiconductor layer part and including a semiconductor layer containing a first concentration of an impurity of the first conductivity type; a step of preparing a fourth semiconductor layer part including a semiconductor layer containing a second concentration, which is lower than the first concentration, of an impurity of the first conductivity type; a step of forming a photonic crystal in at least either the third semiconductor layer part or the fourth semiconductor layer part; and a step of directly bonding the first bonding face of the third semiconductor layer part located opposite the face on which the second semiconductor layer part is disposed and the second bonding face of the fourth semiconductor layer part.

Certain embodiments of the present disclosure can provide a semiconductor laser that includes a photonic crystal and a method of manufacturing the semiconductor laser.

### BRIEF DESCRIPTION OF THE DRAWINGS

FIG. 1A is a schematic cross-sectional view of a semiconductor laser according to Embodiment 1 of the present disclosure.

FIG. 1B is a schematic cross-sectional view showing another form of the photonic crystal in the semiconductor laser shown in FIG. 1A.

FIG. 2 is a schematic top view of the semiconductor laser shown in FIG. 1A.

FIG. 3 is a diagram showing an example of a photonic crystal included in the semiconductor laser shown in FIG. 1A.

FIG. 4A is a schematic cross-sectional view of another form of the photonic crystal in the semiconductor laser shown in FIG. 1A.

FIG. 4B is a schematic cross-sectional view of a semiconductor laser having a distributed Bragg reflector.

FIG. 4C is a schematic cross-sectional view of another semiconductor laser having a distributed Bragg reflector.

FIG. 5A is a schematic cross-sectional view of a semiconductor laser having an antireflective coating applied to the light extraction face.

FIG. 5B is a schematic cross-sectional view of the semiconductor laser shown in FIG. 1A in which the position of the light extraction face is changed.

FIG. 6 is a schematic cross-sectional view of a semiconductor laser according to Embodiment 2 of the present disclosure.

FIG. 7 is a schematic cross-sectional view of a semiconductor laser according to Embodiment 3 of the present disclosure.

FIG. 8A is a schematic cross-sectional view showing a step of a method of manufacturing the semiconductor laser shown in FIG. 1A.

FIG. 8B is a schematic cross-sectional view showing a step of the method of manufacturing the semiconductor laser shown in FIG. 1A.

FIG. 8C is a schematic cross-sectional view showing a step of the method of manufacturing the semiconductor laser shown in FIG. 1A.

FIG. 8D is a schematic cross-sectional view showing a step of the method of manufacturing the semiconductor laser shown in FIG. 1A.

FIG. 8E is a schematic cross-sectional view showing a step of the method of manufacturing the semiconductor laser shown in FIG. 1A.

FIG. 8F is a schematic cross-sectional view showing a step of the method of manufacturing the semiconductor laser shown in FIG. 1A.

FIG. 8G is a schematic cross-sectional view showing a step of the method of manufacturing the semiconductor laser shown in FIG. 1A.

FIG. 9A is a schematic cross-sectional view showing a step of a method of manufacturing the semiconductor laser shown in FIG. 7.

FIG. 9B is a schematic cross-sectional view showing a step of the method of manufacturing the semiconductor laser shown in FIG. 7.

FIG. 9C is a schematic cross-sectional view showing a step of the method of manufacturing the semiconductor laser shown in FIG. 7.

FIG. 9D is a schematic cross-sectional view showing a step of the method of manufacturing the semiconductor laser shown in FIG. 7.

### DETAILED DESCRIPTION

Certain embodiments and examples for implementing the present invention will be explained below with reference to the accompanying drawings. The semiconductor lasers described below are provided for giving shape to the technical ideas of the invention in the present disclosure, but the invention is not limited to the described embodiments unless otherwise specifically stated.

In the drawings, the same reference numerals denote members having the same functions. To make the features easily understood, the descriptions of the features are distributed among the embodiments and examples, but the constituent elements described in different embodiments and examples can be replaced or combined in part. The explanation of common features already described in embodiments or examples appearing earlier might be omitted in the subsequent embodiments or examples where the explanation is focused only on the differences. Similar effects attributable to similar features, in particular, will not be mentioned each time an embodiment or example is discussed. The sizes of and positional relationships between the members shown in each drawing might be exaggerated for clarity of explanation.

In the present specification, a photonic crystal refers to a structure having a refractive index distribution in which the refractive index varies with a period of a length similar to the wavelength of the light emitted from an active layer. A photonic crystal is constructed in one layer in some cases, and across multiple layers in other cases. A photonic crystal is made up of a first refractive index portion made of a first refractive index medium and a plurality of second refractive index portions made of a second refractive index medium that is different from the first refractive index medium arranged in the first refractive index portion, in which at least some of the second refractive index portions are periodically arranged. Preferably, a photonic crystal is constructed such that all of the second refractive index portions made of a second refractive index medium are periodically arranged in the first refractive index portion made of a first refractive index medium. When the periodic arrangement of the second refractive index portions is one dimensional, the semiconductor laser is a distributed feedback laser (DFB laser). When the periodic arrangement of the second refractive index portions is two dimensional, the semiconductor laser is a photonic crystal surface emitting laser (PCSEL). The periodic arrangement being one-dimensional means that the refractive index changes periodically in one of the in-plane directions in the drawings, i.e., either the first direction (e.g., x direction) or the second direction (e.g. y direction). The periodic arrangement being two-dimensional means that the refractive index changes periodically in both of the in-plane directions in the drawings, i.e., both the first direction (e.g., x direction) and the second direction (e.g., y direction). In the case of a two-dimensional periodic arrangement, the period in the first direction may be the same as or different from the period in the second direction. When focusing on the second refractive index portions in a photonic crystal, a set of two adjacent second refractive index portions may be considered as the minimum unit that is set as a period. A set that includes three or more second refractive index portions can alternatively be considered as a refractive index change period. The refractive index changes resulting from such a set of three or more second refractive index portions may generate undulations of refractive indices in the x direction and/or y direction. Furthermore, the photonic crystal may include crystal defects to the extent that such defects do not interfere with the laser oscillation of a DFB or PCSEL laser. Examples of crystal defects are those attributable to crystal growth, etching process damage, or the like.

In the present specification, direct bonding refers to the direct bonding of the third semiconductor layer part 30 and the fourth semiconductor layer part 40 without interposing any resin or adhesive. In the case in which the third semiconductor layer part 30 and the fourth semiconductor layer part 40 are directly bonded, the third semiconductor layer part 30 and the fourth semiconductor layer part 40 are not simply in contact, but are interatomically bonded. This can achieve a high bonding strength. Interatomic bonding can be observed by using, for example, a high resolution electron microscope. Direct bonding can be achieved by, for example, surface activated bonding or atomic diffusion bonding.

### EMBODIMENTS

### 1. Embodiment 1

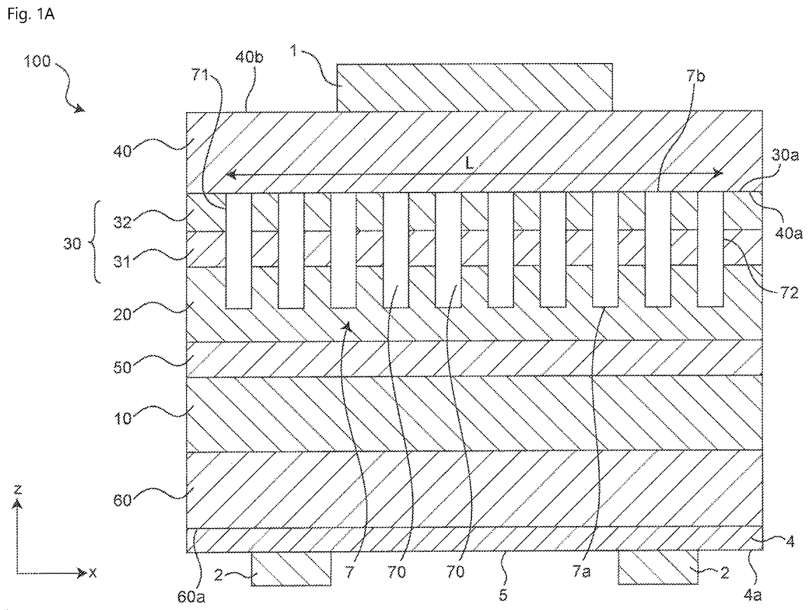

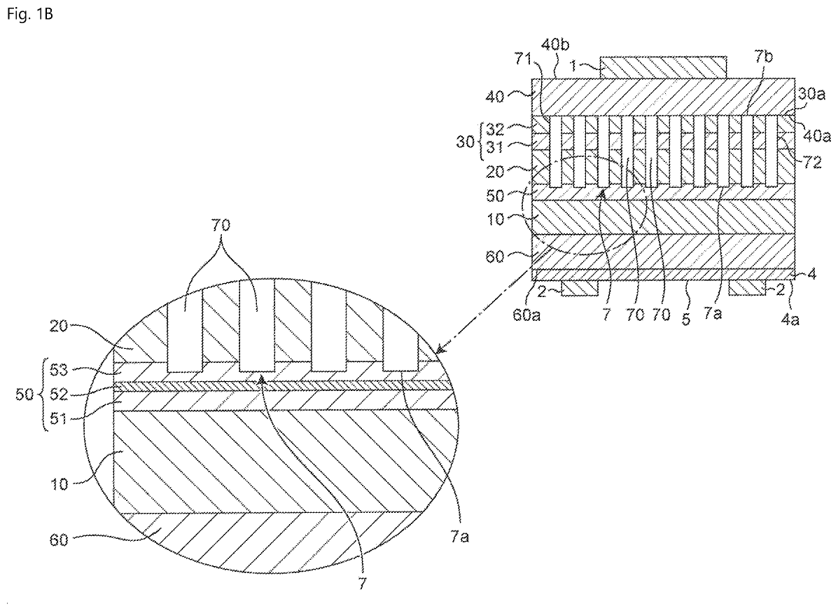

A semiconductor laser 100 according to Embodiment 1 is a photonic crystal surface emitting laser (PCSEL). The semiconductor laser 100 according to Embodiment 1 will be explained below with reference to FIG. 1A to FIG. 5B.

As shown in FIG. 1A, the semiconductor laser 100 includes a first semiconductor layer part 10 disposed on a substrate 60, an active layer 50 disposed on the first semiconductor layer part 10, a second semiconductor layer part 20 disposed on the active layer 50, a third semiconductor layer part 30 disposed on the second semiconductor layer part 20, and a fourth semiconductor layer part 40 disposed on the third semiconductor layer part 30.

The first semiconductor layer part 10 includes a semiconductor layer of a first conductivity type.

The second semiconductor layer part 20 includes a semiconductor layer of a second conductivity type.

The third semiconductor layer part 30 includes a semiconductor layer containing a first concentration of an impurity of the first conductivity type.

The fourth semiconductor layer part 40 includes a semiconductor layer containing a second concentration of an impurity of the first conductivity type. The second concentration is lower than the first concentration, i.e., the first concentration is higher than the second concentration.

In this embodiment, the first conductivity type is n-type, and the second conductivity type is p-type.

The third semiconductor layer part 30 is directly bonded to the fourth semiconductor layer part 40. The third semiconductor layer part 30 includes a photonic crystal.

A first electrode 1 is electrically connected to the fourth semiconductor layer part 40, and a second electrode 2 is electrically connected to the first semiconductor layer part 10 via the substrate 60.

In the semiconductor laser 100, which is a photonic crystal surface emitting laser, the light from the active layer 50 forms a standing wave and resonates in the photonic crystal. The resonating light exits the photonic crystal as laser light in the up and down directions (+z direction and −z direction). The laser light oscillating in the up and down directions in the semiconductor laser 100 can have, for example, the same wavelength and the same intensity. In this embodiment, the light exiting downward and the light exiting upward and reflected by the first electrode 1 exit from the bottom of the semiconductor laser 100. A light transmissive electrode 4 may be disposed on the lower face 60a of the substrate 60. Accordingly, the light extraction face of a semiconductor laser 100 not provided with a light transmissive electrode 4 is included in the lower face 60a of the substrate 60. The light extraction face of the semiconductor laser 100 provided with a light transmissive electrode 4 is included in the lower face 4a of the light transmissive electrode 4.

### Substrate

A substrate 60 contains an impurity of the first conductivity type, and has conductivity. The substrate 60 is, for example, an n-type GaN substrate. The thickness of the substrate 60 has only to be large enough to diffuse the current injected into the semiconductor laser 100 in the in-plane directions within a predetermined range, for example, 10 μm to 500 μm, preferably 50 μm to 500 μm, more preferably 50 μm to 100 μm. A buffer layer may be disposed between the substrate 60 and the first semiconductor layer part 10. The semiconductor laser 100 does not have to have a substrate 60.

### First Semiconductor Layer Part

A semiconductor layer of a first conductivity type included in a first semiconductor layer part 10 is, for example, a nitride semiconductor layer containing an n-type impurity, such as silicon (Si), germanium (Ge), or the like. In other words, the first conductivity type is n-type, and the first semiconductor layer part 10 includes an n-type nitride semiconductor layer. The n-type impurity concentration of the first semiconductor layer part 10 may be, for example, 1×10¹⁸ cm⁻³ to 5×10¹⁹ cm⁻³. In this embodiment, the first semiconductor layer part 10 is a nitride semiconductor layer part. As described later, the second semiconductor layer part 20, the third semiconductor layer part 30, and the fourth semiconductor layer part 40 are also nitride semiconductor layer parts. Forming each layer part as a nitride semiconductor layer part allows each layer part to have transmissivity with respect to the oscillation wavelength. The first semiconductor layer part 10, the second semiconductor layer part 20, the third semiconductor layer part 30, and the fourth semiconductor layer part 40 can have larger bandgap energies than the bandgap energies of the well layers described later. This allows each semiconductor layer part to transmit the light emitted by the active layer thereby increasing the light extraction efficiency.

The first semiconductor layer part 10 includes one or more semiconductor layers of the first conductivity type. The first semiconductor layer part 10 may include an undoped semiconductor layer in part. Here, the undoped semiconductor layer refers to a layer to which n-type and/or p-type impurity is not intentionally added. An undoped layer may have an impurity concentration below the detectable limit in a secondary ion mass spectroscopy (SIMS) analysis or the like. The impurity concentration of an undoped layer in the case of containing Si as an n-type impurity is, for example, 1×10¹⁶/cm⁻³ or lower, and in the case of containing Ge as an n-type impurity is 1×10¹⁷/cm⁻³ or lower. The first semiconductor layer part 10 is, for example, 1 μm to 5 μm in thickness. The first semiconductor layer part 10 includes, for example, an n-type GaN layer, and the thickness of the n-type GaN layer can be set to 0.1 μm to 5 μm, preferably 0.1 μm to 0.5 μm. In the case in which the n-type GaN layer contains Si as an n-type impurity, the n-type GaN layer's impurity concentration can be set, for example, to 1×10¹⁸ cm⁻³ to 5×10¹⁹ cm⁻³. The first semiconductor layer part 10 is not limited to GaN, and may contain In and/or Al.

### Active Layer

As shown in FIGS. 1A and 1B, an active layer 50 is an emission layer disposed on the first semiconductor layer part 10. The light emitted by the active layer 50 has a peak emission wavelength falling within the 200 nm to 760 nm range, for example. The active layer 50 has, for example, a quantum well structure that includes one or more well layers 52 and a plurality of barrier layers. The quantum well structure may be, for example, a multiple quantum well structure having a plurality of well layers and a plurality of barrier layers. In the case in which the active layer 50 has a quantum well structure and emits light falling within the wavelength range described above, the well layers and the barrier layers are, for example, GaN, InGaN, AlGaN, or AlInGaN. The well layers are, for example, AlGaN, GaN, or InGaN, which are nitride semiconductors having smaller band gap energies than the barrier layers. A superlattice layer in which undoped GaN layers and undoped InGaN layers are alternately stacked may be formed between the first semiconductor layer part 10 and the active layer 50. The barrier layers include at least the first barrier layer 51 that is in contact with the first semiconductor layer part 10 and the second barrier layer 53 that is in contact with the second semiconductor layer part 20.

### Second Semiconductor Layer Part

A semiconductor layer of the second conductivity type included in a second semiconductor layer part 20 is, for example, a nitride semiconductor layer containing a p-type impurity such as magnesium (Mg). The second semiconductor layer part 20 includes one or more second conductivity type semiconductor layers. The impurity concentration of the p-type impurity may be, for example, 1×10¹⁶ cm⁻³ to 3×10²² cm⁻³. A second conductivity type semiconductor layer is, for example, a p-type GaN layer. The second conductivity type semiconductor layer may contain In and/or Al. The thickness of the p-type GaN layer can be set to 0.04 μm to 1.5 μm, preferably 0.04 μm to 0.5 μm. In the case in which the p-type GaN layer contains Mg as a p-type impurity, the impurity concentration of the p-type GaN layer can be set, for example, to 1×10¹⁶ cm⁻³ to 3×10²² cm⁻³, preferably 5×10¹⁶ cm⁻³ to 1×10²¹ cm⁻³. The second semiconductor layer part 20 may include an undoped semiconductor layer. In order to form a tunnel junction with the first layer 31 described later, at least the layer in contact with the first layer 31 is preferably a nitride semiconductor layer containing a p-type impurity, and the impurity concentration can be 1×10²⁰ cm⁻³ to 3×10²² cm⁻³.

### Third Semiconductor Layer Part

A third semiconductor layer part 30 that forms a pn junction with the second semiconductor layer part 20 can form a so-called tunnel junction. The first bonding face 30a of the third semiconductor layer part 30 located opposite the face on which the second semiconductor layer part 20 is disposed can be directly bonded to the second bonding face 40a of the fourth semiconductor layer part 40 described later by, for example, surface activated bonding or the like.

A tunnel junction can be formed by increasing at least the p-type impurity concentration of a p-type semiconductor layer or the n-type impurity concentration of a n-type semiconductor layer. In order to increase the probability of the transmission of electrons through the depletion layer in the tunnel junction, the smaller the width of the depletion layer formed by the pn junction of the p-type semiconductor layer and the n-type semiconductor layer, the more preferable it is. The higher the concentration of at least either the p-type impurity concentration or the n-type impurity concentration, the smaller the width of the depletion layer can be.

The third semiconductor layer part 30 in this embodiment has, for example, a first layer 31 and a second layer 32 successively formed from the second semiconductor layer part 20 side. In this embodiment, the width of the depletion layer of the pn junction is made relatively small by increasing the n-type impurity concentration of the first layer 31 that forms the tunnel junction, thereby facilitating the transmission of electrons through the depletion layer. The first layer 31 is a nitride semiconductor layer containing a first concentration of an impurity of the first conductivity type (n-type). The first concentration may be set, for example, to 1×10¹⁹ cm⁻³ to 5×10²² cm⁻³. The second layer 32 is a nitride semiconductor layer containing a third concentration of an impurity of the first conductivity type (n-type), the third concentration being lower than the first concentration. The third concentration is lower than the first concentration. This can make the crystallinity of the second layer 32 higher than that of the first layer 31, thereby forming a fully planarized surface when directly bonding the second layer 32 to the fourth semiconductor layer part 40 described later. Furthermore, the third concentration of the second layer 32 is higher than the n-type impurity concentration of the fourth semiconductor layer part 40 described later. Thus, the current injected when the semiconductor laser is driven can easily diffuse in the in-plane directions, i.e., in the width direction (x direction) and the depth direction (y direction) in the drawings. The third concentration may be set, for example, to 1×10¹⁸ cm⁻³ to 1×10²⁰ cm⁻³.

The impurity concentration of the first layer 31 can be set, for example, to 1×10¹⁹ cm⁻³ to 5×10²² cm⁻³, preferably 5×10¹⁹ cm⁻³ to 1×10²¹ cm⁻³, more preferably 1×10²⁰ cm⁻³ to 1×10²¹ cm⁻³. The thickness of the first layer 31 can be set, for example, to 1 nm to 500 nm, preferably 1 nm to 300 nm. The first layer 31 can include n-type GaN. In the case in which the n-type GaN layer contains Si as an n-type impurity, the impurity concentration of the n-type GaN layer can be set, for example, to 1×10¹⁹ cm⁻³ to 5×10²² cm⁻³, preferably 5×10¹⁹ cm⁻³ to 1×10²¹ cm⁻³, more preferably 1×10²⁰ cm⁻³ to 1×10²¹ cm⁻³. This allows for the formation of a tunnel junction between the second semiconductor layer part 20 and the third semiconductor layer part 30, thereby reducing the forward voltage increase. This can also diffuse current in the in-plane directions, i.e., in the width direction (x direction) and the depth direction (y direction) in the drawings. The second layer 32 includes, for example, an n-type GaN layer, and the thickness of the n-type GaN layer can be set to 10 nm to 500 nm, preferably 50 nm to 300 nm. In the case in which the n-type GaN layer included in the second layer 32 contains Si as an n-type impurity, the impurity concentration of the n-type GaN layer can be set lower than the impurity concentration of the n-type GaN layer included in the first layer 31, for example, 1×10¹⁸ cm⁻³ to 1×10²⁰ cm⁻³, preferably 1×10¹⁹ cm⁻³ to 5×10¹⁹ cm 3.

The third semiconductor layer part 30 includes a photonic crystal 7. In the semiconductor laser 100, the photonic crystal 7 allows the light from the active layer 50 to resonate in the in-plane directions (x and y directions in the drawings) and oscillate in the up and down directions (+z and −z directions in the drawings). The semiconductor laser 100 equipped with a photonic crystal 7 can emit laser light with reduced higher order modes. The semiconductor laser 100 can emit, for example, single mode light in both transverse mode and longitudinal mode.

### Photonic Crystal

A photonic crystal 7 in this embodiment is disposed at least in the third semiconductor layer part 30. The first refractive index portion is the third semiconductor layer part 30 having a nitride semiconductor as the first refractive index medium, for example. The second refractive index portions are holes 70 arranged in the first refractive index portion, and the second refractive index medium is, for example, air. The photonic crystal 7 includes, for example, cylindrical holes 70 and, for example, a portion of the third semiconductor layer part 30 and/or the second semiconductor layer part 20. The diameter of each hole 70 may be, for example, 20 nm to 150 nm or 20 nm to 80 nm. The depth of each hole 70 may be 50 nm to 2500 nm, 100 nm to 1000 nm, or 300 nm to 600 nm. The shape of each hole 70 may be columnar, conical, or pyramidal. The cross sectional shape of each hole 70 is not limited to a circle, and may be, for example, elliptical or polygonal. For example, each hole 70 can be a vacuum or filled with air, a rare gas such as argon, or a dielectric having a smaller refractive index than that of GaN as the second refractive index medium. The dielectric is, for example, SiO₂. This can increase the coupling efficiency of the photonic crystal and resonating light.

The holes 70 included in the photonic crystal can be created to form, for example, a square lattice, rectangular lattice, or triangular lattice when viewed from above. Assuming that the wavelength in vacuum is λ and the effective refractive index is n_{eff}, two holes separated by 1/(4× n_{eff}×λ) in the x and y directions can be created per unit cell. Such a structure is referred to as a double-hole lattice structure. Such a double-hole lattice structure allows for the emission of laser light with reduced occurrences of higher order modes even for a large emission area. For example, the transverse mode and the longitudinal mode can be maintained as a single mode. Alternatively, the holes 70 may be created such that two different periodic lattice structures overlap. For example, a square lattice having a lattice constant a₁ in both the x and y directions may be laid over a rectangular lattice having a lattice constant a₁ in either the x or y direction of the in-plane directions and a lattice constant a₂ in the other direction. In this manner, as compared to the case with only one type of lattice structure, a new band edge can be formed at a location shifted from the F point by a predetermined wavenumber δk=π(1/a₁−1/a₂) in the in-plane wave vector direction. Utilizing such a band edge allows the emission direction of the laser light to incline by the angle θ=sin⁻¹(δk/k₀), k₀=2π/λ, with respect to the direction perpendicular to the emission face. This can control the emission direction of the laser light. The lattice constant a₂ can be continuously changed within a predetermined range.

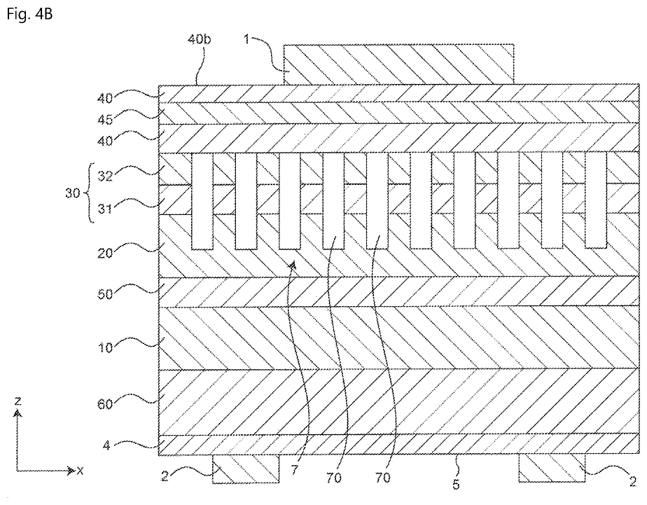

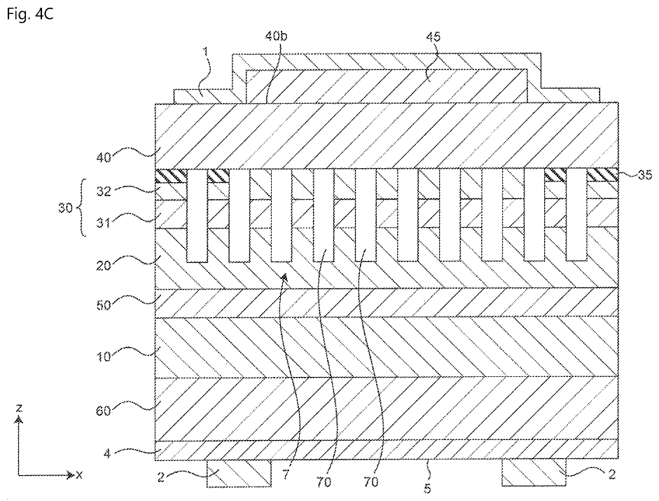

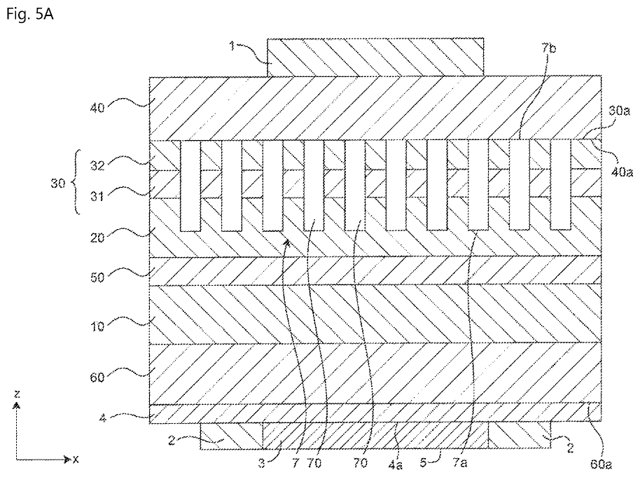

The upper ends 7b of the holes 70 constituting the photonic crystal 7 are located in the second bonding face 40a of the fourth semiconductor layer part 40. In this embodiment, the lower ends 7a of the holes 70 constituting the photonic crystal 7 are located in the second semiconductor layer part 20 as shown in FIG. 1A. Alternatively, for example, the lower ends 7a of the holes 70 may be located in the third semiconductor layer part 30 as shown in FIG. 4A. The closer the lower ends 7a of the holes 70 to the active layer 50, the easier it is for the light from the active layer 50 to reach the photonic crystal 7 while the light intensity attenuation is small. This can increase the light intensity in the photonic crystal 7. Accordingly, the lower ends 7a of the holes 70 are preferably located in the second semiconductor layer part 20 rather than in the third semiconductor layer part 30. The lower ends 7a of the holes 70 may be located in the active layer 50 or the first semiconductor layer part 10. In the case in which the lower ends 7a of the holes 70 are located in the active layer 50 or the first semiconductor layer part 10, the volume of the active layer 50 is reduced as compared to the case in which the lower ends 7a of the holes 70 are located in the third semiconductor layer part 30 or the second semiconductor layer part 20. This can reduce the threshold current. In this case, moreover, the amount of light confined in the photonic crystal 7 is increased. This can reduce the threshold current of the semiconductor laser 100 that is the current for laser light oscillation. In the case in which the lower ends 7a of the holes 70 are located in the active layer 50, the lower ends 7a of the holes 70 may be located in the second barrier layer 53. This can increase the percentage of secondary diffraction in the photonic crystal while reducing the threshold current density. At this time, the diameter of each hole 70 may be 20 nm to 80 nm, and the depth 300 nm to 600 nm, for example. The depth of a hole 70 refers to the distance from the upper end 7b to the lower end 7a of the hole 70.

In the semiconductor laser 100, current can be diffused in the in-plane directions in the third semiconductor layer part 30 that forms a tunnel junction with the second semiconductor layer part 20, and the second semiconductor layer part 20. This can also diffuse the current immediately under the insulating holes 70.

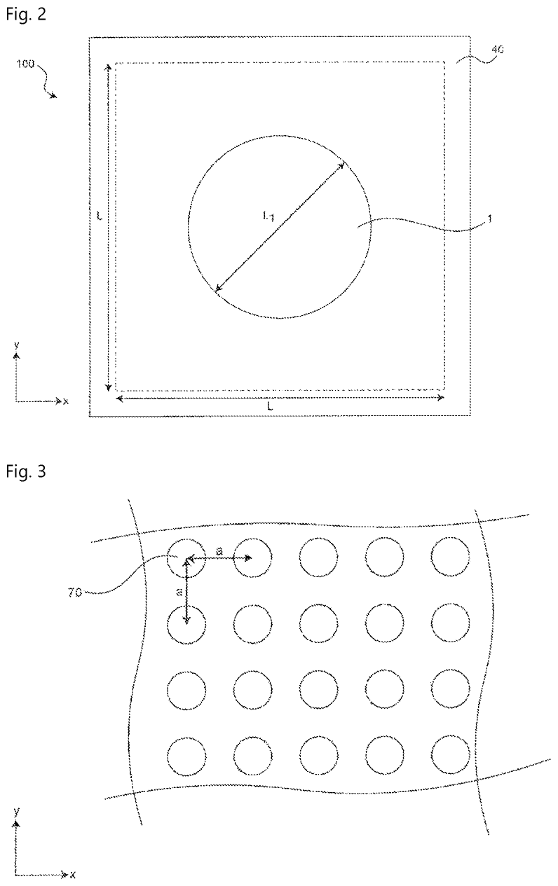

In this embodiment, as shown in FIG. 2, the outline of the semiconductor laser 100 when viewed from above is a square shape in which the length in the width direction (x direction) equals the length in the depth direction (y direction). As shown by the broken lines in FIG. 2, the region in which the photonic crystal 7 is formed when seen through from above can approximate the square whose lengths in the width and depth directions are lengths L that are equal. Here, the lengths L are the lengths from the outermost first end 71 to the outermost second end 72 located opposite the first end 71 of the photonic crystal 7 in the width direction cross section shown in FIG. 1A, and the depth direction cross section. The length L is, for example, 0.5 mm to 2 mm, preferably 0.8 mm to 1.5 mm. The outline of the photonic crystal 7 when seen through from above is not limited to the quadrangle described above. For example, the shape may be a circle having a diameter L. The diameter is, for example, 0.5 mm to 2 mm, preferably 0.8 mm to 1.5 mm.

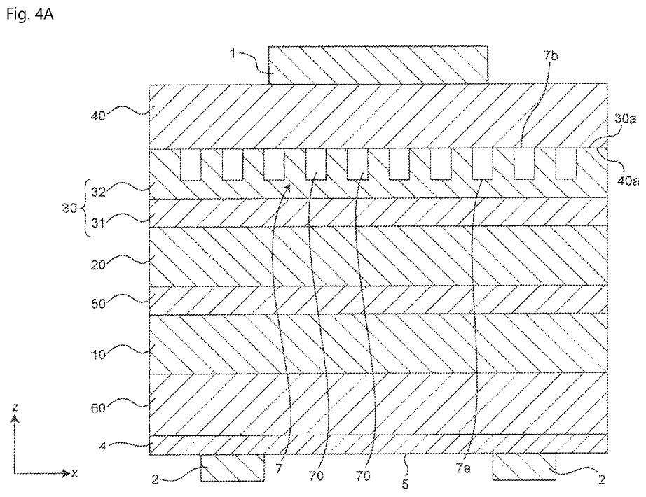

The lattice constant a of the photonic crystal shown in FIG. 3, the wavelength λ in vacuum, and the effective refractive index n_{eff} satisfy the relation equation, a=λ/n_{eff}.

Here, the effective refractive index n_{eff} is a weighted average refractive index of the refractive index of the substrate, the refractive index of each of the semiconductor layers and the active layer by assigning weights based on the intensity distribution of the light propagating in each layer. The effective refractive index n_{eff} in Embodiment 1 is an average refractive index of the refractive indices of the substrate 60, the first semiconductor layer part 10, the active layer 50, the second semiconductor layer part 20, the third semiconductor layer part 30, and the fourth semiconductor layer part 40 that are assigned weights based on the intensity distribution of the light propagating each semiconductor layer part and the active layer. For the effective refractive index n_{eff}, a target value can be estimated by simulation. In the actual manufacturing, because the lattice constant a of the photonic crystal and the wavelength λ in vacuum can be measured, the effective refractive index n_{eff} can be estimated by the relation equation, n_{eff}=λ/a obtained by turning around the relation equation described earlier. Because the lattice constant a of the photonic crystal and the wavelength λ in vacuum can vary due to manufacturing variances, the effective refractive index n_{eff} estimated by simulation might not necessarily match the effective refractive index n_{eff} estimated by using the relation equation in actual manufacturing.

In the case of a semiconductor laser element that emits blue light, for example, the effective refractive index n_{eff} can be 2.4 to 2.5, and the lattice constant a of the photonic crystal 7 in the 180 nm to 200 nm range. In the case of a semiconductor laser element that emits green light, for example, the effective refractive index n_{eff} can be 2.3 to 2.4, and the lattice constant a of the photonic crystal 7 in the 210 nm to 230 nm range. In the case of a semiconductor laser element that emits red light, for example, the effective refractive index n_{eff} can be 2.2 to 2.3, and the lattice constant a of the photonic crystal 7 in the 250 nm to 280 nm range.

### Fourth Semiconductor Layer Part

A fourth semiconductor layer part 40 contains a second concentration of an n-type impurity (impurity of the first conductivity type). The second concentration is lower than the first concentration and the third concentration. The second concentration that is lower than the first concentration and the third concentration can be set, for example, to 1×10¹⁸ cm⁻³ to 5×10¹⁹ cm⁻³. As described above, the fourth semiconductor layer part 40 is directly bonded to the third semiconductor layer part 30 by, for example, surface activated bonding. In other words, the fourth semiconductor layer part 40 and the third semiconductor layer part 30 are in contact with one another without interposing an adhesive. Directly bonding the fourth semiconductor layer part 40 and the third semiconductor layer part 30 can reduce the contact resistance between the fourth semiconductor layer part 40 and the third semiconductor layer part 30.

The material for constructing the fourth semiconductor layer part 40 is desirably the same as the material for constructing the third semiconductor layer part 30. In other words, the third semiconductor layer part 30 and the fourth semiconductor layer part 40 are desirably constructed with the same material. Matching the material for the fourth semiconductor layer part 40 and the third semiconductor layer part 30 can make it easier to control the effective refractive index. Furthermore, using the same material for the fourth semiconductor layer part 40 and the third semiconductor layer part 30 can make the thermal expansion coefficients of the two parts to be identical, thereby increasing the bonding strength between the fourth semiconductor layer part 40 and the third semiconductor layer part 30. The material for constructing the fourth semiconductor layer part 40 and the third semiconductor layer part 30 being the same has only to be the base material for the two semiconductor layer parts being the same, and the impurity concentration may differ. For example, the fourth semiconductor layer part 40 and the third semiconductor layer part 30 are both nitride semiconductor layers, for example, n-type GaN layers.

The refractive index of the fourth semiconductor layer part 40 is preferably higher than the average refractive index of the photonic crystal 7. The average refractive index of the photonic crystal 7 refers to the average refractive index of the refractive index of the holes 70 and the refractive index of the semiconductor layer part in which the holes 70 are provided. Providing such a fourth semiconductor layer part 40 on the photonic crystal 7 can distribute the light intensity to the fourth semiconductor layer part 40 as well. This can increase the light intensity in the photonic crystal as well as increasing the amount of resonance contributing light, thereby efficiently achieving laser oscillation as compared to the case in which no fourth semiconductor layer part is disposed where the upper face of the third semiconductor layer part 30 is contacting air.

The thickness of the fourth semiconductor layer part 40 may be, for example, 1 μm to 500 μm, preferably 1 μm to 400 μm, more preferably 1 μm to 10 μm. In the case in which the n-type GaN layer contains Si as an n-type impurity, the impurity concentration of the n-type GaN layer can be set, for example, to 1×10¹⁸ cm⁻³ to 5×10¹⁹ cm⁻³. It is desirable to suitably adjust the thickness of the fourth semiconductor layer part 40 in accordance with the size of the contact area with the first electrode 1 described later.

As described above, providing a fourth semiconductor layer part 40 can provide the fourth semiconductor layer part 40 with light intensity as well as increase the light intensity of the semiconductor layer part that includes a photonic crystal. Furthermore, setting the conditions of the fourth semiconductor layer part 40, such as the thickness and the refractive index, to fall within the predetermined ranges can maximize the light intensity in the active layer 50. Maximizing the light intensity of the active layer 50 in the state in which the light intensity is increased in the semiconductor layer part that includes the photonic crystal can achieve a highly efficient surface emitting semiconductor laser 100.

As shown in FIG. 4B and FIG. 4C, a distributed Bragg reflector (DBR film) 45 may be disposed in the fourth semiconductor layer part 40 or on the upper face 40b of the fourth semiconductor layer part 40. The DBR film can be obtained by stacking two or more pairs of SiO₂/Nb₂O₅, for example. The pairs of layers constituting a DBR film may alternatively be SiO₂/Ta₂O₅ pairs, SiO₂/Al₂O₃ pairs, or Si-doped GaN/Si-doped AlInN pairs. This allows the light resonated in the photonic crystal 7 and exiting upwards to be reflected downwards, thereby increasing the light extraction efficiency of the semiconductor laser.

### First Electrode and Second Electrode

A first electrode 1 is a light reflecting member as well as a conductive member. The material for the first electrode 1 is Ag or Al, for example. The first electrode 1 is located at a position that overlaps the photonic crystal 7 in a plan view. In this embodiment, the first electrode 1 is an anode and is disposed on the upper face 40b of the fourth semiconductor layer part 40. Because the light resonated in the photonic crystal 7 is laser oscillated in the up and down directions, the first electrode 1 disposed on the fourth semiconductor layer part 40 so as to overlap the photonic crystal 7 can reflect the light oscillating upwards towards the lower part of the semiconductor laser 100. This can improve the light extraction efficiency.

The shape of the first electrode 1 when viewed from above may be a circle having a diameter L₁ as shown in FIG. 2, for example. This can achieve isotropic current diffusion in the in-plane directions, facilitating efficient current injection. The diameter of the first electrode 1 is not restricted, but is preferably smaller than the major axis of the region where a photonic crystal 7 is formed when seen through from above. Furthermore, the first electrode 1 is preferably located inside the region in which a photonic crystal 7 is formed when seen through from above. This can create a region in the photonic crystal 7 where the current is injected and a region where the current is not readily injected. The spatial distribution of light confined in the photonic crystal 7 is determined by the structure of the photonic crystal, and does not depend on the size of the electrode. Accordingly, employing an electrode structure that restricts the current injection region can control the region where a gain occurs. Disposing the first electrode 1 in the central portion of the photonic crystal 7 when viewed from above can reduce the leakage of light from the photonic crystal. This can reduce the necessary current for driving the semiconductor laser 100. Moreover, the region in the photonic crystal 7 into which current is not readily injected functions as a reflecting mirror to revert the light leaking in the in-plane directions to the region into which current is injected, thereby reducing the decline in the amount of resonance contributing light. The top view shape of the first electrode 1 is not limited to a circle, and may be a polygon, such as a square, rectangle, triangle, or the like.

In the case in which the DBR film 45 is disposed on the upper face 40b of the fourth semiconductor layer part 40 to overlap the photonic crystal 7 at least in part in a plan view, the first electrode 1 may be disposed so as not to partially overlap the DBR film 45, or at least partially overlap the DBR film 45 as shown in FIG. 4B or 4C. In the case of providing a DBR film 45, the first electrode 1 does not have to be a light reflecting member. In the case of providing a DBR film 45, the first electrode 1 does not have to be located to overlap the photonic crystal 7 in a plan view. In the case of disposing the first electrode 1 to overlap the DBR film 45 at least in part, as shown in FIG. 4C, the fourth semiconductor layer part 40 may be 1 μm to 450 μm in thickness, for example. This allows the current to also diffuse immediately under the DBR film 45. In order to reduce the current flow from immediately under the first electrode 1 located on the lateral faces of the DBR film 45 towards the second electrode 2, insulating portions 35 are preferably provided in at least either the third semiconductor layer part 30 or the fourth semiconductor layer part 40 as shown in FIG. 4C. For example, the insulating regions 35 are provided by injecting ions or forming grooves in the second layer 32 of the third semiconductor layer part 30 immediately under the first electrode 1 located on the lateral faces of the DBR film 45. Alternatively, insulating portions 35 may be formed in the fourth semiconductor layer part 40 by using a similar method. An insulating portion 35 is disposed in thickness of 5 nm to 200 nm, preferably 10 nm to 100 nm from the bonding interface. This can effectively diffuse the current immediately under the DBR film 45. Accordingly, the active layer in the region immediately under the DBR film 45 emits light upon current injection, and a portion of the resonated light is reflected by the DBR film 45 to be extracted through the light extraction face 5.

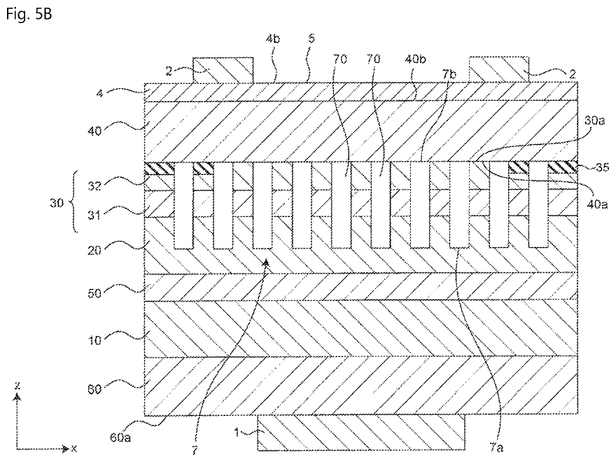

A second electrode 2 is a conductive member. The second electrode 2 can be formed by using a single layer film or multilayer film of Al, Ti, Pt, Au or the like, for example. A multilayer film is one composed of Ti, Pt, and Au, for example. In this embodiment, the second electrode 2 is a cathode. The second electrode 2 is, for example, a ring shaped electrode disposed to surround the photonic crystal 7 in a plan view. The second electrode 2 may be a ring-shaped electrode disposed to overlap the photonic crystal 7 in a plan view. As shown in FIG. 5A, moreover, an antireflective coating 3 may be applied to the lower face 60a of the substrate 60 located inside the ring. Applying an antireflective coating 3 as described above can reduce the returning light as a result of reflection occurring between the substrate 60 and air, thereby reducing the loss of light. At this time, the lower face of the antireflective coating 3 becomes the light extraction face 5. A light transmissive electrode 4 may be further provided between the substrate 60 and the second electrode 2. Examples of the materials for the light transmissive electrode 4 include ITO.

Here, as shown in FIG. 5B, the first electrode 1 that has light reflectivity and conductivity may be disposed on the lower face 60a of the substrate 60 at the location that overlaps the photonic crystal 7 in a plan view. Moreover, the second electrode 2 having conductivity may be disposed on the upper face 40b of the fourth semiconductor layer part 40. A light transmissive electrode 4 may be further disposed between the second electrode 2 and the fourth semiconductor layer part 40. The first electrode 1 disposed on the lower face 60a of the substrate 60 functions as a cathode, and the second electrode 2 disposed on the upper face 40b of the fourth semiconductor layer part 40 functions as an anode. By positioning the first electrode 1 and the second electrode 2 in this manner, light can be extracted from the upper face 40b of the fourth semiconductor layer part 40. In other words, the light extraction face is included in the upper face 40a of the fourth semiconductor layer part 40 if no light transmissive electrode 4 is provided, and the light extraction face is included in the upper face 4b of the light transmissive electrode 4 if provided. In such a form, a DBR film 45 may be disposed on the lower face 60a side of the substrate 60. In this case, the first electrode 1 can be disposed to surround the DBR film 45, or under the DBR film 45 in addition to surrounding the DBR film 45.

A PCSEL in the case in which a photonic crystal 7 is constructed with a first refractive index portion that includes at least a third semiconductor layer part 30 and second refractive index portions made up of holes 70 has been explained above, but this embodiment is not limited to this. The photonic crystal 7 may be constructed with a first refractive index portion made of a first refractive index medium, for example, a vacuum, air, a rare gas, or a dielectric such as SiO₂, and second refractive index portions made of a second refractive index medium made up of cylindrical semiconductor layer parts. This can reduce the threshold current of the PCSEL.

### 2. Embodiment 2

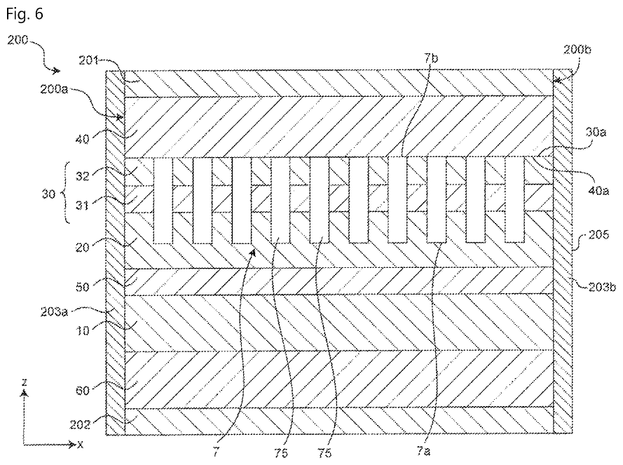

The semiconductor laser 200 according to this embodiment shown in FIG. 6 differs from the semiconductor laser 100 according to Embodiment 1 such that it is a distributed feedback laser. The periodic changes of the refractive index of the photonic crystal 7 are achieved by a first refractive index portion, including at least a portion of the third semiconductor layer part 30, and second refractive index portions composed of grooves 75 arranged in the semiconductor layer. The first refractive index medium that forms the first refractive index portion is, for example, a GaN-based semiconductor, and the second refractive index medium that forms the second refractive index portions is, for example, a vacuum or air. The lattice constant a of the photonic crystal, the emission wavelength λ in vacuum, and the effective refractive index n_{eff} satisfy the relation equation, a=λ1(2× n_{eff}). This allows for laser light emission with reduced occurrences of higher order modes from the cleaved end face. For example, the semiconductor laser 200 can emit laser light of a single transverse mode.

The semiconductor laser 200 according to this embodiment is provided with light reflecting films 203a and 203b on the end faces 200a and 200b of the semiconductor layer part. Each of the light reflecting films 203a and 203b is, for example, a single layer or multilayer film of Al₂O₃, ZrO₂, or SiO₂. The reflectivity of the light reflecting film 203b is lower than the reflectivity of the light reflecting film 203a. In the semiconductor laser 200, the light emitted by the active layer 50 resonates between the end faces and exits from the light extraction face 205 that is the end face 200b.

### 3. Embodiment 3

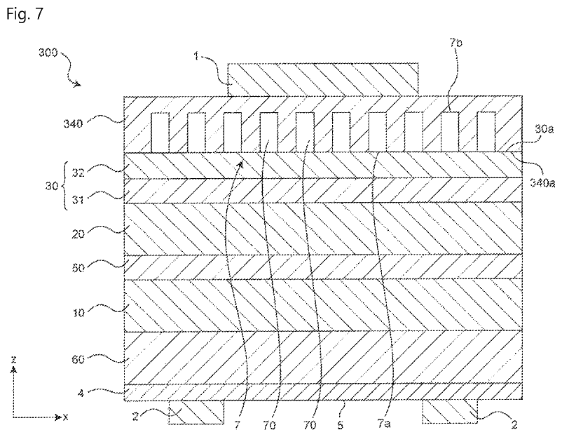

A semiconductor laser 300 according to this embodiment is the same as the semiconductor laser 100 according to Embodiment 1 in the sense that it is a PCSEL, but differs from the semiconductor laser 100 according to Embodiment 1 such that the photonic crystal is formed in the fourth semiconductor layer part 340 as shown in FIG. 7. In the semiconductor laser 300, the lower ends 7a of the holes 70 that constitute the photonic crystal 7 are located in the second bonding face 340a of the fourth semiconductor layer part 340. The upper ends 7b of the holes 70 that constitute the photonic crystal 7 are located in the fourth semiconductor layer part 340.

### Manufacturing Methods

### 1. Example of Method of Manufacturing Semiconductor Laser of Embodiment 1

### (Manufacturing Method 1)

Manufacturing Method 1 includes:
(1) a step of preparing a semiconductor part that includes a first semiconductor layer part 10 including a semiconductor layer of a first conductivity type, an active layer 50 disposed on the first semiconductor layer part 10, a second semiconductor layer part 20 disposed on the active layer 50 and including a semiconductor layer of a second conductivity type, and a third semiconductor layer part 30 disposed on the second semiconductor layer part 20 and including a semiconductor layer containing a first concentration of an impurity of the first conductivity type,
(2) a step of preparing a fourth semiconductor layer part 40 including a semiconductor layer containing a second concentration, which is lower than the first concentration, of an impurity of the first conductivity type,
(3) a step of forming a photonic crystal in the third semiconductor layer part 30, and
(4) a step of directly bonding the first bonding face 30a of the third semiconductor layer part 30 located opposite the face on which the second semiconductor layer part 20 is provided and the second bonding face 40a of the fourth semiconductor layer part 40.

A semiconductor laser 100 is manufactured by MOCVD (metalorganic chemical vapor deposition) in a pressure and temperature adjustable chamber. Each semiconductor layer part or semiconductor layer can be formed by introducing into the chamber a carrier gas and a source gas. For the carrier gas, hydrogen (H₂) gas or nitrogen (N₂) gas can be used. For the N source gas, ammonia (NH₃) gas can be used. For the Ga source gas, a trimethyl gallium (TMG) gas, or a triethyl gallium (TEG) gas can be used. For the In source gas, a trimethyl indium (TMI) gas can be used. For the Al source gas, a trimethyl aluminum (TMA) gas can be used. For the Si source gas, a monosilane (SiH₄) gas can be used. For the Mg source gas, a bis(cyclopentadienyl)magnesium (Cp₂Mg) gas can be used. In the example of a manufacturing method described below, each layer part or layer is epitaxially grown by MOCVD. MOCVD is a technique that excels in terms of mass productivity. In addition to MOCVD, remote plasma-enhanced CVD may be utilized. Utilizing a remote plasma-enhanced CVD technique can increase the carrier density in a semiconductor layer. In addition, a physical vapor deposition (PVD) technique may be used. Utilizing a PVD technique can introduce more carriers. PVD techniques include sputtering and molecular beam epitaxy (MBE).

### Step of Preparing Semiconductor Part

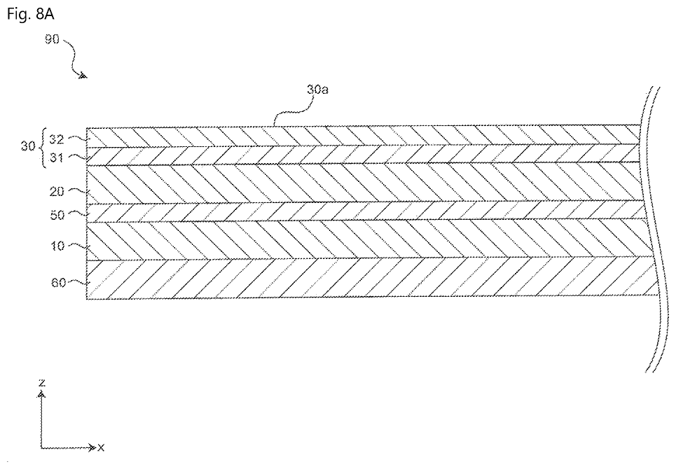

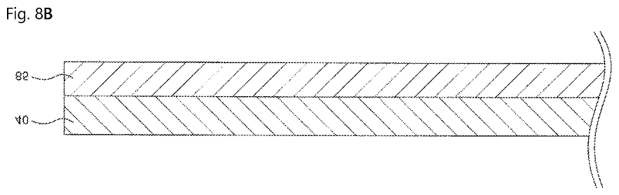

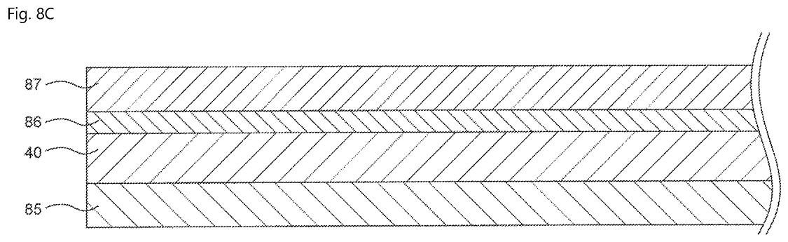

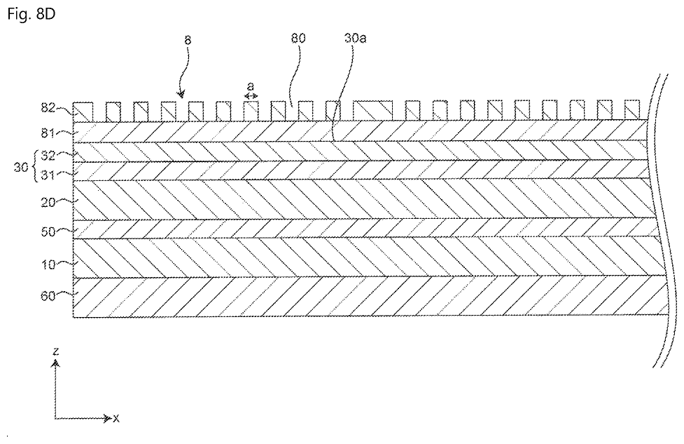

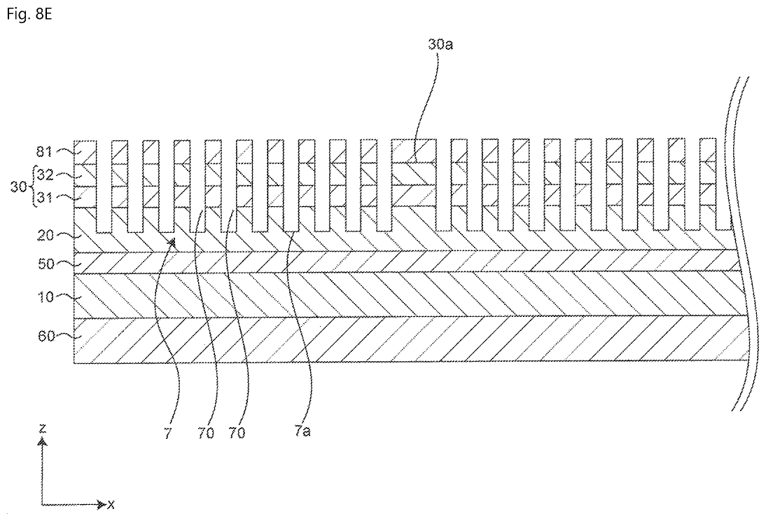

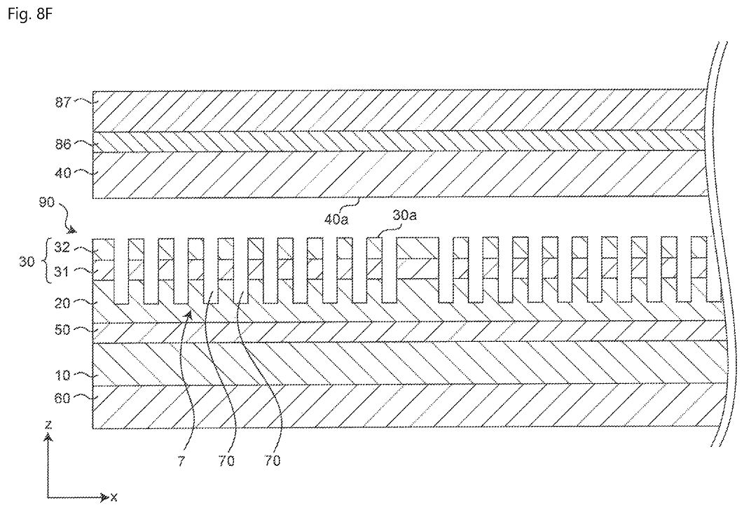

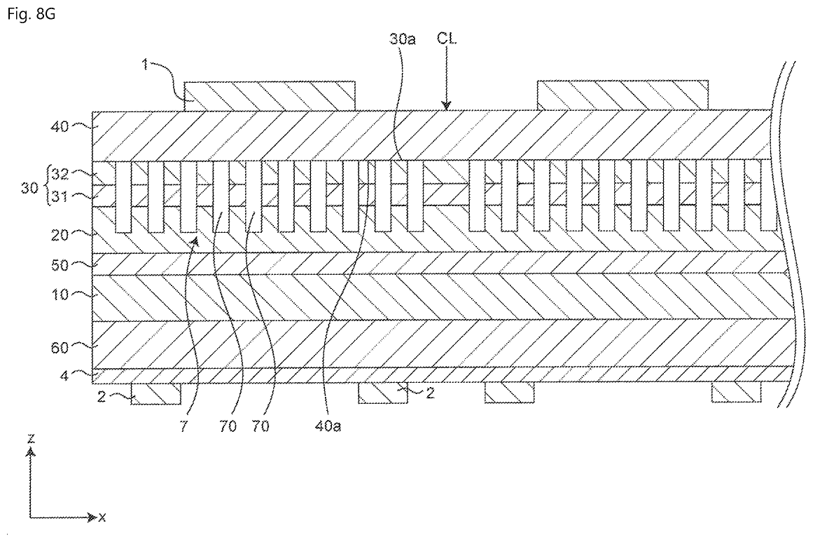

A step of preparing a semiconductor part 90 will be explained with reference to FIG. 8A.

First, a substrate 60 made of n-type GaN, for example, is prepared.

Then a semiconductor part 90 is prepared by forming on the substrate 60, successively from the substrate 60 side, a first semiconductor layer part 10 including a semiconductor layer of a first conductivity type (n-type), an active layer 50, a second semiconductor layer part 20 including a semiconductor layer of a second conductivity type (p-type), and a third semiconductor layer part 30 including a semiconductor layer containing a first concentration of an impurity of the first conductivity type. The formation of the third semiconductor layer part 30 is conducted by forming successively from the substrate 60 side a first layer 31 and a second layer 32.

A first semiconductor layer part 10 is formed by growing an n-type clad layer on the substrate 60, for example. The first semiconductor layer part 10 may be formed after disposing a buffer layer on the substrate 60. An undoped semiconductor layer may be further disposed between the buffer layer and the n-type clad layer.

Then an active layer 50 is formed on the first semiconductor layer part 10. In the case in which the active layer 50 is a multiple quantum well structure, for example, the active layer 50 is formed by alternately depositing desired numbers of barrier layers and well layers from the substrate 60 side. In this case, the step of forming the active layer 50 ends with the process of forming a barrier layer.

Then on the active layer 50, a second semiconductor layer part 20 is formed by growing, for example, a p-type clad layer.

Then a third semiconductor layer part 30 that includes a first layer 31 and a second layer 32 is formed on the second semiconductor layer part 20.

First, on the second semiconductor layer part 20, a first layer 31 that is a semiconductor layer containing a first concentration of an n-type impurity (an impurity of the first conductivity type) is grown. The first layer 31 is, for example, n-type GaN, and may contain In and/or Al. The first concentration is, for example, 5×10¹⁹ cm⁻³ to 5×10²² cm⁻³, preferably 1×10²⁰ cm⁻³ to 1×10²¹ cm⁻³.

The first layer 31 containing a first concentration of an n-type impurity can be formed by introducing a carrier gas, a source gas for forming the first layer 31, and a source gas containing an n-type impurity element. For example, when the n-type impurity is Si, the first layer 31 containing a first concentration of an n-type impurity can be formed by supplying a source gas containing Si to the source gas for forming the first layer 31 at a predetermined flow rate.

Then on the first layer 31, a second layer 32 containing a third concentration of an n-type impurity (an impurity of the first conductivity type) is grown. The third concentration is lower than the first concentration. The third concentration is higher than the second concentration of the n-type impurity contained in the fourth semiconductor layer part 40 described later. The material for constructing the second layer 32 is desirably the same as the material for constructing the first layer 31. The second layer 32 is, for example, n-type GaN, and may contain In and/or Al. The third concentration is, for example, 1×10¹⁸ cm⁻³ to 1×10²⁰ cm⁻³, preferably 1×10¹⁹ cm⁻³ to 5×10¹⁹ cm⁻³.

The second layer 32 containing a third concentration of an n-type impurity can be formed by introducing an n-type impurity element into the source gas for forming the second layer 32. For example, when the n-type impurity is Si, the second layer 32 containing a third concentration of an n-type impurity can be formed by supplying a source gas containing Si to the source gas for forming the second layer 32 at a predetermined flow rate.

### Step of Preparing Fourth Semiconductor Layer Part

Next, a semiconductor layer part 40 containing a second concentration of an n-type impurity is prepared. The material for constructing the fourth semiconductor layer part 40 is desirably the same as the material for constructing the third semiconductor layer 30. The fourth semiconductor layer part 40 is, for example, GaN. The thickness of the fourth semiconductor layer part 40 may be, for example, 1 μm to 500 μm, preferably 1 μm to 400 μm, more preferably 1 μm to 10 μm. First, as shown in FIG. 8B, a fourth semiconductor layer part 40 made of a nitride semiconductor containing an n-type impurity is grown by MOCVD on a growth substrate 85 made of sapphire. Then, as shown in FIG. 8C, a resin layer 86 and a support substrate 87 are successively disposed on the fourth semiconductor layer part 40, and the growth substrate 85 is subsequently removed.

### Step of Forming Photonic Crystal

Next, a photonic crystal is formed by creating a plurality of holes at least in the third semiconductor layer part. The photonic crystal can be formed by the method described below, for example. As shown in FIG. 8D, the first bonding face 30a of the third semiconductor layer part 30 is covered with a first mask 81 made of SiO₂ or the like. This can increase the selectivity of the third semiconductor layer part 30 to the first mask 81 in the etching process described later. A second mask 82 made of a resin or the like is further disposed on the upper face of the first mask 81. This can increase the selectivity of the second mask 82 to the first mask 81 in the lithography process described later. The second mask 82 is provided with a collective hole part 8 that includes a plurality of holes created at predetermined intervals. The collective hole part 8 is formed by electron beam lithography or nanoimprint lithography, for example. In the case in which holes 80 are created to form a square lattice as shown in FIG. 3, for example, the distance between the centers of adjacent holes 80 represents the lattice constant a of the photonic crystal 7. The lattice constant a and the wavelength λ in vacuum, and the effective refractive index n_{eff} satisfy the relation equation, a=λ/n_{eff}.

Then as shown in FIG. 8E, the photonic crystal 7 is formed by removing the first mask 81, the third semiconductor layer part 30, and the second semiconductor layer part 20 exposed from the second mask 82 thereby creating holes 70 to a predetermined depth so as to position the lower ends 7a in the second semiconductor layer part 20. The first mask 81, the third semiconductor layer part 30, and the second semiconductor layer part 20 can be removed by etching, for example, reactive ion etching using a chlorine-containing gas. Forming the holes 70 by using the first mask 81 and the second mask 82 can increase the aspect ratio of the holes 70. At this time, the etching depth can be changed to locate the lower ends 7a of the holes 70 in the third semiconductor layer part 30. Subsequently, the first mask 81 is removed. The second mask 82 in many cases is removed during the reactive ion etching. In some cases, an adjustment of the depth of the holes 70 might cause the second mask 82 to remain in part. In such a case, the second mask 82 is also removed together with the first mask 81.

### Direct Bonding Step

Then as shown in FIG. 8F, the first bonding face 30a of the third semiconductor layer part 30 located opposite the face on which the second semiconductor layer part 20 is disposed and the second bonding face 40a of the fourth semiconductor layer part 40 are directly bonded. The first bonding face 30a and the second bonding face 40a can be directly bonded by surface activated bonding, for example. Surface activated bonding is a method in which both the first bonding face 30a and the second bonding face 40a are planarized and cleaned before bonding.

The planarization process can be conducted by, for example, chemical mechanical polishing (CMP), dipping in an acidic or alkaline solution, or the like. These processes can achieve a planar face having an arithmetic average roughness Ra of, for example, 1 nm or lower, preferably 0.5 nm or lower. For the planarization process, dipping in an acidic or alkaline solution is preferable in the case of planarizing a+c-plane of GaN. This can remove the polycrystals present on the first principal face. For the acidic or alkaline solution, for example, H₂SO₄ (sulfuric acid), HF (hydrofluoric acid), HCl (hydrochloric acid), TMAH (tetramethylammonium hydroxide), or KOH (hydroxide potassium) can be used. For the acidic or alkaline solution, TMAH can preferably be used. In the case of planarizing a −c-plane of GaN, it is preferably planarized by CMP. This can achieve the second bonding face having an arithmetic average roughness of 1 nm or lower, preferably 0.5 nm or lower.

In the bonding step, the first bonding face 30a and the second bonding face 40a that are activated by sputter etching using an argon ion beam or plasma are directly bonded under predetermined conditions. The bonding temperature is, for example, 0° C. to 100° C., preferably 0° C. to 70° C., more preferably 0° C. to 50° C. Unlike fusing, surface activated bonding does not require a high temperature and can achieve firm bonding at a relatively low temperature. Because the upper end of the photonic crystal 7 is closed after forming the photonic crystal 7, thermal damage to the active layer can be reduced as compared to the case in which the fourth semiconductor layer part 40 is formed by MOCVD or PVD. Moreover, in the case of closing the upper end by crystal growth, the hole shape and size can be restricted by the conditions for closing the upper end. Closing the upper end by direct bonding, however, can increase the degree of freedom in designing the holes. The pressure applied during the surface activated bonding is, for example, 10 MPa to 200 MPa, preferably 50 MPa to 100 MPa.

When bonding in the direct bonding step, the crystal axial direction in the first crystal plane may be, but does not have to be, aligned with the crystal axial direction in the second crystal plane. Assuming that the first crystal plane is a+c-plane and the second crystal plane is a −c-plane, for example, these two crystal planes may be bonded by shifting the in-plane a-axis direction of the first crystal plane (+c-plane) from the in-plane a-axis direction of the second crystal plane (−c-plane). This eliminates the necessity of aligning the crystal orientations of the bonding faces in the direct bonding step, thereby simplifying the manufacturing step. According to the manufacturing method of Embodiment 1, even if the crystal axial direction in the first crystal plane is not aligned with the crystal axial direction in the second crystal plane during direct bonding, the crystal planes (the first crystal plane and the second crystal plane) can be bonded with one another. The misalignment of the crystal axes can be confirmed by observing the rotational symmetry of an asymmetric surface by performing XRD φ rotation scanning. The misalignment of the crystal axes between the first crystal plane and the second crystal plane can be observed repeatedly in accordance with the rotational symmetry. The asymmetric surface, for example, is the (102) plane of gallium nitride.

In the direct bonding step, moreover, the first bonding face 30a and the second bonding face 40a can be annealed after directly bonding the two. This can reduce the electrical resistance of the semiconductor laser. This is believed to be because annealing can enhance the adhesion while maintaining the crystallinity in the vicinity of the bonding interface. Annealing is performed, for example, without applying any pressure. The annealing temperature is, for example, within the 300° C. to 500° C. range, preferably the 350° C. to 450° C. range. The annealing temperature is suitably set within the ranges described above according to the nitride semiconductor materials used for the third semiconductor layer part 30 and the fourth semiconductor layer part 40. For example, in the case of forming both the third semiconductor layer part 30 and the fourth semiconductor layer part 40 with GaN, it is believed that annealing at a temperature within the above ranges can improve the adhesion between the third semiconductor layer part 30 and the fourth semiconductor layer part 40 while maintaining the crystallinity.

Furthermore, the annealing step can simultaneously heat the resin layer 86 and the support substrate 87 disposed on the fourth semiconductor layer part 40. In other words, the annealing step can remove the support substrate 87 by melting or burning off the resin layer 86. Accordingly, the fourth semiconductor layer part 40 is less likely to be separated from the third semiconductor layer part 30 when removing the support substrate 87 from the resin layer 86. After removing the resin layer 86 and the support substrate 87, the surface of the fourth semiconductor layer part 40 is cleaned, and a first electrode 1 can be formed on the cleaned surface. The resin layer 86 and the support substrate 87 may be removed by another method before forming the first electrode 1. Furthermore, a substrate that includes the fourth semiconductor layer part 40 can be directly bonded to the third semiconductor layer part 30 without using a resin layer 86 or support substrate 87.

By following the photonic crystal forming step and the direct bonding step described above, a photonic crystal 7 can be formed in the third semiconductor layer part 30, and the upper ends 7b of the holes 70 constituting the photonic crystal 7 arranged in the second bonding face 40a of the fourth semiconductor layer part 40.

### Electrode Forming Step

Next, as shown in FIG. 8G, first electrodes 1 are formed on the upper face 40b of the fourth semiconductor layer part 40 using a predetermined pattern, and second electrodes 2 are formed on the lower face 60a of the substrate 60 using a predetermined pattern. A light transmissive electrode 4 may be further formed between the second electrodes 2 and the substrate 60. The first electrodes 1 are disposed to overlap the photonic crystal 7 at least in part in a plan view.

The first electrodes and the second electrodes 2 can be formed by suitably using a known technique. The first electrodes 1 and the second electrodes 2 can be formed by, for example, a lift-off process or etching process using a resist.

### Singulation Step

Next, the structure is divided into individual semiconductor lasers 100. The singulation is conducted by laser scribing or dicing along a predetermined singulation position CL such as that shown in FIG. 8G. Laser scribing is a wafer dividing technique that utilizes a crack propagating from a modified zone in a substrate created by focusing a laser beam.

### 2. Example of Method of Manufacturing Semiconductor Laser of Embodiment 2

### (Manufacturing Method 2)

Manufacturing Method 2 differs from Manufacturing Method 1 for a semiconductor laser 100 of Embodiment 1 by including, in addition to what is included in Manufacturing Method 1, a step of disposing a light reflecting film 203a on the end face 200a and a light reflecting film 203b on the end face 200b.

The step of disposing a light reflecting film 203a and a light reflecting film 203b is conducted subsequent to or during the singulation step. The light reflecting film 203a and the light reflecting film 203b are formed by, for example, vacuum vapor deposition or sputtering.

In the step of forming a photonic crystal 7 in this method, grooves 75 are provided such that the lattice constant a, the wavelength λ in vacuum, and the effective refractive index n_{eff} satisfy the relation equation, a=λ/(2×n_{eff}). The periodic changes of the refractive index achieved by the grooves 75 is one dimensional. In other words, a semiconductor laser manufactured by Manufacturing Method 2 is a DFB laser.

### 3. Example of Method of Manufacturing Semiconductor Laser of Embodiment 3

### (Manufacturing Method 3)

Manufacturing Method 3 differs from Manufacturing Method 1 for a semiconductor laser of Embodiment 1 in terms of the step of forming a photonic crystal 7.

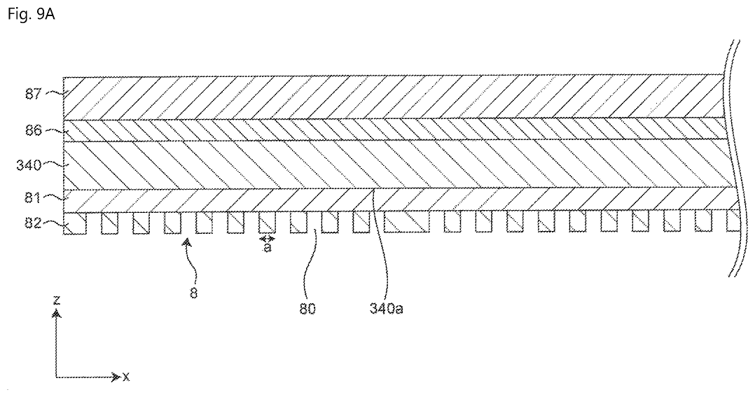

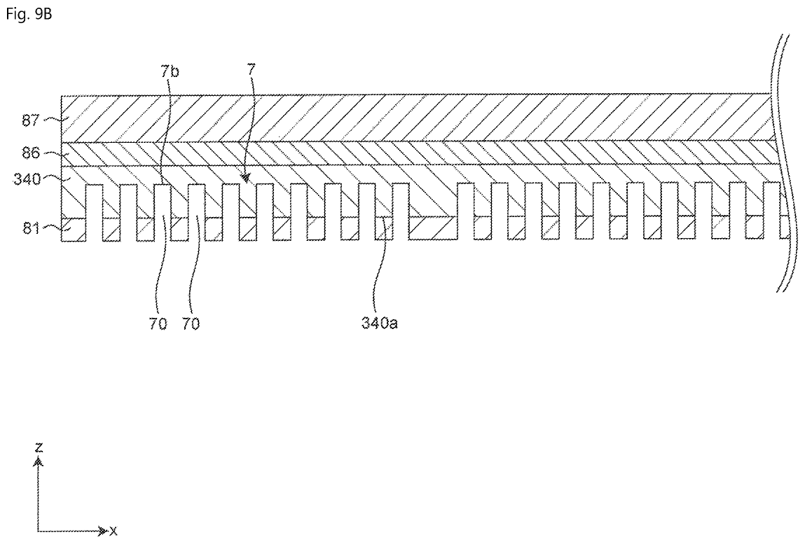

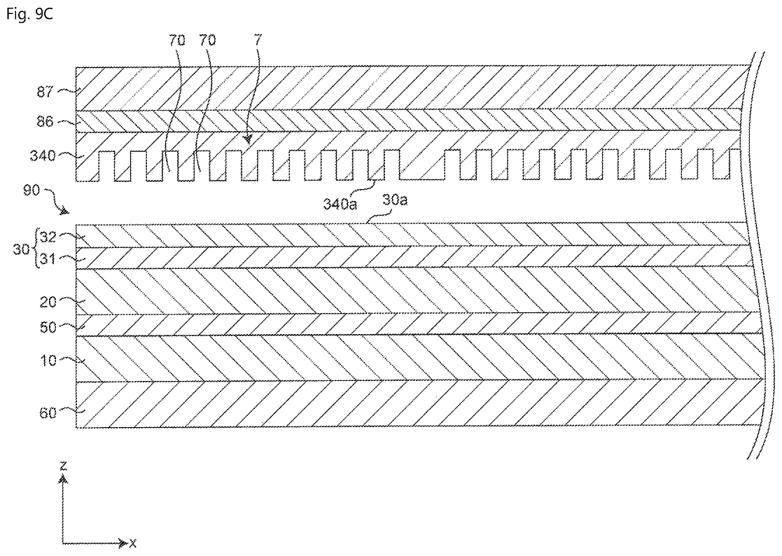

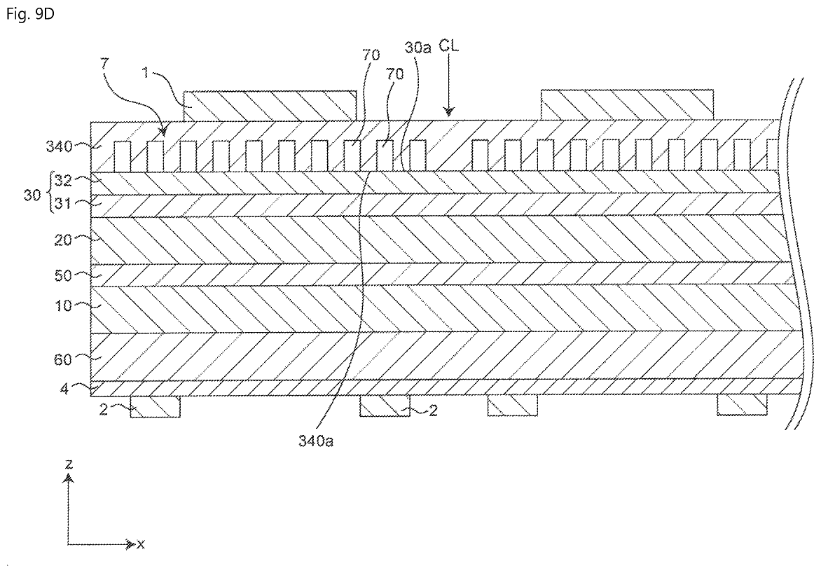

In the step of forming a photonic crystal 7 in Manufacturing Method 3, a photonic crystal 7 is formed in the fourth semiconductor layer part 340. Specifically, as shown in FIG. 9A, a first mask 81 and a second mask 82 having a collective hole part 8 are disposed on the second bonding face 340a of the fourth semiconductor layer part 340. Then as shown in FIG. 9B, the first mask 81 and the fourth semiconductor layer part 340 exposed from the second mask 82 are removed to thereby form holes 70 such that the upper ends 7b of the holes 70 constituting a photonic crystal 7 are located in the fourth semiconductor layer part 340.

The step of preparing a semiconductor part 90, the step of preparing a fourth semiconductor layer part 40, the direct bonding step shown in FIG. 9C, and the electrode forming step and the singulation step shown in FIG. 9D are similar to the respective steps in Manufacturing Method 1.

In the manufacturing method described above, a photonic crystal 7 is formed in the fourth semiconductor layer part 340 that does not have the active layer 50, followed by bonding the fourth semiconductor layer part 340 and the semiconductor part 90 that has an active layer 50. This method can reduce the damage to the active layer 50 attributable to etching or the like.

For example, the present invention can be constructed as described below.

### Item 1

A semiconductor laser comprising:
a first semiconductor layer part including a semiconductor layer of a first conductivity type;
an active layer disposed on the first semiconductor layer part;
a second semiconductor layer part disposed on the active layer and including a semiconductor layer of a second conductivity type;
a third semiconductor layer part disposed on the second semiconductor layer part and including a semiconductor layer containing a first concentration of an impurity of the first conductivity type; and
a fourth semiconductor layer part disposed on the third semiconductor layer part and including a second concentration of the impurity of the first conductivity type,
the first concentration being higher than the second concentration,
the third semiconductor layer part being directly bonded to the fourth semiconductor layer part, and
at least either the third semiconductor layer part or the fourth semiconductor layer part including a photonic crystal.

### Item 2

The semiconductor laser disclosed in Item 1, wherein
the third semiconductor layer part includes:
a first layer, which is the semiconductor layer containing a first concentration of the impurity of the first conductivity type and
a second layer, which is a semiconductor layer containing a third concentration of the impurity of the first conductivity type, the third concentration being higher than the second concentration but lower than the first concentration,
the first layer and the second layer being disposed successively from the second semiconductor layer part side.

### Item 3

The semiconductor laser disclosed in Item 1 or 2, wherein the third semiconductor layer part includes the photonic crystal, the upper ends of the holes constituting the photonic crystal being located in the bonding face of the fourth semiconductor layer part.

### Item 4

The semiconductor laser disclosed in any of Items 1 to 3, wherein the lower ends of the holes constituting the photonic crystal are located in the second semiconductor layer part.

### Item 5

The semiconductor laser disclosed in any of Items 1 to 3, wherein
the active layer includes one or more well layers and a plurality of barrier layers,
the barrier layers including at least the first barrier layer in contact with the first semiconductor layer part and the second barrier layer in contact with the second semiconductor layer part 20, and
the lower ends of the holes constituting the photonic crystal are located in the second barrier layer.

### Item 6

The semiconductor laser disclosed in any of Items 1 to 5, wherein the third semiconductor layer part and the fourth semiconductor layer part are composed of the same material.

### Item 7

The semiconductor laser disclosed in any of Items 1 to 6, wherein the first semiconductor layer part, the second semiconductor layer part, the third semiconductor layer part, and the fourth semiconductor layer part are each a nitride semiconductor layer part.

### Item 8

The semiconductor laser disclosed in any of Items 1 to 7, wherein the first conductivity type is n-type and the second conductivity type is p-type.

### Item 9

A method of manufacturing a semiconductor laser comprising:
a step of preparing a semiconductor part that includes a first semiconductor layer part including a semiconductor layer of a first conductivity type, an active layer disposed on the first semiconductor layer part, a second semiconductor layer part disposed on the active layer and including a semiconductor layer of a second conductivity type, and a third semiconductor layer part disposed on the second semiconductor layer part and including a semiconductor layer containing a first concentration of an impurity of the first conductivity type;
a step of preparing a fourth semiconductor layer part including a semiconductor layer containing a second concentration, which is lower than the first concentration, of the impurity of the first conductivity type;
a step of forming a photonic crystal in at least either the third semiconductor layer part or the fourth semiconductor layer part; and
a step of directly bonding the first bonding face of the third semiconductor layer part located opposite the face on which the second semiconductor layer part is disposed and the second bonding face of the fourth semiconductor layer part.

### Item 10

The method of manufacturing a semiconductor laser disclosed in Item 9, wherein the direct bonding step is conducted by surface activated bonding.

### Item 11

The method of manufacturing a semiconductor laser disclosed in Item 9 or 10, wherein
in the step of preparing a semiconductor part,
the third semiconductor layer part includes a first layer, which is the semiconductor layer containing a first concentration of the impurity of the first conductivity type, and a second layer, which is a semiconductor layer containing a third concentration of the impurity of the first conductivity type, the third concentration being higher than the second concentration but lower than the first concentration.

### Item 12

The method of manufacturing a semiconductor laser disclosed in any of Items 9 to 11, wherein
in the step of forming a photonic crystal, the photonic crystal is formed by forming a plurality of holes in the third semiconductor layer part, the upper ends of the holes being located in the bonding face of the fourth semiconductor layer part.

### Item 13

The method of manufacturing a semiconductor laser disclosed in any of Items 9 to 12, wherein, in the step of preparing a semiconductor part, the third semiconductor layer part is made of the same material as that for the fourth semiconductor layer part.

Certain embodiments and variations of the present invention have been described above. However, changes may be made to the details of the elements disclosed above, allowing for various modifications to the combinations or the sequences of the elements without deviating from the scope of the claims or the spirit of the invention.

What is claimed is:

1. A semiconductor laser comprising:
a first semiconductor layer part comprising a semiconductor layer of a first conductivity type;
an active layer disposed on the first semiconductor layer part;
a second semiconductor layer part disposed on the active layer and comprising a semiconductor layer of a second conductivity type;
a third semiconductor layer part disposed on the second semiconductor layer part and comprising a semiconductor layer containing a first concentration of an impurity of the first conductivity type; and
a fourth semiconductor layer part disposed on the third semiconductor layer part and comprising a semiconductor layer containing a second concentration of the impurity of the first conductivity type, the second concentration being lower than the first concentration, wherein:
the third semiconductor layer part is directly bonded to the fourth semiconductor layer part, and
at least one of the third semiconductor layer part or the fourth semiconductor layer part comprises a photonic crystal.

2. The semiconductor laser according to claim 1, wherein:
the third semiconductor layer part comprises:
a first layer, which is the semiconductor layer containing the first concentration of the impurity of the first conductivity type, and
a second layer, which is a semiconductor layer containing a third concentration of the impurity of the first conductivity type, the third concentration being higher than the second concentration but lower than the first concentration, wherein:
the first layer and the second layer are disposed successively from the second semiconductor layer part side.

3. The semiconductor laser according to claim 1, wherein:
the third semiconductor layer part comprises the photonic crystal, and upper ends of holes constituting the photonic crystal are located in a bonding face of the fourth semiconductor layer part.

4. The semiconductor laser according to claim 2, wherein:
the third semiconductor layer part comprises the photonic crystal, and upper ends of holes constituting the photonic crystal are located in a bonding face of the fourth semiconductor layer part.

5. The semiconductor laser according to claim 1, wherein:
lower ends of holes constituting the photonic crystal are located in the second semiconductor layer part.

6. The semiconductor laser according to claim 1, wherein:
the active layer comprises one or more well layers, and a plurality of barrier layers;
the plurality of barrier layers includes at least a first barrier layer in contact with the first semiconductor layer part and a second barrier layer in contact with the second semiconductor layer part, and
lower ends of the holes constituting the photonic crystal are located in the second barrier layer.

7. The semiconductor laser according to claim 1, wherein:
the third semiconductor layer part and the fourth semiconductor layer part are made of the same material.

8. The semiconductor laser according to claim 2, wherein:
the third semiconductor layer part and the fourth semiconductor layer part are made of the same material.

9. The semiconductor laser according to claim 1, wherein:
the first semiconductor layer part, the second semiconductor layer part, the third semiconductor layer part, and the fourth semiconductor layer part are each a nitride semiconductor layer part.

10. The semiconductor laser according to claim 2, wherein:
the first semiconductor layer part, the second semiconductor layer part, the third semiconductor layer part, and the fourth semiconductor layer part are each a nitride semiconductor layer part.

11. The semiconductor laser according to claim 1, wherein:
the first conductivity type is n-type and the second conductivity type is p-type.

12. A method of manufacturing a semiconductor laser comprising:
a step of preparing a semiconductor part that comprises:
a first semiconductor layer part comprising a semiconductor layer of a first conductivity type,
an active layer disposed on the first semiconductor layer part, a second semiconductor layer part disposed on the active layer and comprises a semiconductor layer of a second conductivity type, and
a third semiconductor layer part disposed on the second semiconductor layer part and comprising a semiconductor layer containing a first concentration of an impurity of the first conductivity type;
a step of preparing a fourth semiconductor layer part comprising a semiconductor layer containing a second concentration of the impurity of the first conductivity type, the second concentration being lower than the first concentration;
a step of forming a photonic crystal in at least one of the third semiconductor layer part or the fourth semiconductor layer part; and
a step of directly bonding a bonding face of the third semiconductor layer part located opposite a face on which the second semiconductor layer part is disposed and a bonding face of the fourth semiconductor layer part.

13. The method of manufacturing a semiconductor laser according to claim 12, wherein:
the step of directly bonding is conducted by surface activated bonding.

14. The method of manufacturing a semiconductor laser according to claim 12, wherein:
in the step of preparing the semiconductor part, the third semiconductor layer part comprises:
a first layer, which is the semiconductor layer containing the first concentration of the impurity of the first conductivity type, and
a second layer, which is a semiconductor layer containing a third concentration of the impurity of the first conductivity type, the third concentration being higher than the second concentration but lower than the first concentration.

15. The method of manufacturing a semiconductor laser according to claim 12, wherein:
in the step of forming a photonic crystal, the photonic crystal is formed by forming a plurality of holes in the third semiconductor layer part, upper ends of the holes being located in the bonding face of the fourth semiconductor layer part.

16. The method of manufacturing a semiconductor laser according to claim 13, wherein
in the step of forming a photonic crystal, the photonic crystal is formed by forming a plurality of holes in the third semiconductor layer part, upper ends of the holes being located in the bonding face of the fourth semiconductor layer part.

17. The method of manufacturing a semiconductor laser according to claim 14, wherein
in the step of forming a photonic crystal, the photonic crystal is formed by forming a plurality of holes in the third semiconductor layer part, upper ends of the holes being located in the bonding face of the fourth semiconductor layer part.

18. The method of manufacturing a semiconductor laser according to claim 12, wherein, in the step of preparing the semiconductor part, the third semiconductor layer part and the fourth semiconductor layer part are made of the same material.
